(19) United States
(12) Patent Application Publication
(10) Pub. No.: US 2026/0362986 A1
(43) Pub. Date: Nov. 12, 2026

(54) SUPERCONDUCTOR AND METHOD FOR MANUFACTURING SUPERCONDUCTOR

(71) Applicant: Tokyo Metropolitan Public University Corporation, Tokyo (JP)

(72) Inventors: Aichi Yamashita, Tokyo (JP); Yoshikazu Mizuguchi, Tokyo (JP); Mahiro Yamanaka, Tokyo (JP); Toshiniko Maeda, Kami-shi (JP); Naoko Oono, Yokohama-shi (JP); Kota Sakurai, Yokohama-shi (JP)

(21) Appl. No.: 19/488,368

(22) PCT Filed: May 21, 2024
(86) PCT No.: PCT/JP2024/018667

§ 371 Date: Nov. 26, 2025

(30) Foreign Application Priority Data
May 29, 2023 (JP) 2023-087946

(51) Int. Cl. H10N 60/85; H10N 60/01

(52) U.S. Cl. CPC H10N 60/85; H10N 60/01

(57) ABSTRACT

A superconductor is represented by General Formula (1).

REBa₂Cu₃O_{7-δ} (1)

(in Formula (1), RE is composed of Y, Gd, and X, X is composed of one or multiple species of elements selected from the group consisting of La, Ce, Pr, Nd, Sm, Eu, Tb, Dy, Ho, Er, Tm, Yb, and Lu, and 0≤δ≤1)

### TECHNICAL FIELD

The present invention relates to a superconductor and a method for manufacturing a superconductor.

Priority is claimed on Japanese Patent Application No. 2023-087946, filed May 29, 2023, the contents of which is incorporated herein by reference.

### BACKGROUND ART

In recent years, superconducting instruments such as power transmission cables, superconducting electromagnets, and superconducting current leads using a superconductor as a low-current loss material have been treated as one of highly efficient and low-current loss electrical instruments capable of resolving energy, environmental, and resource issues (for example, Patent Document 1), Patent Document 1 discloses the use of a Nb₃Sn compound superconductor and a Nb₃Al compound superconductor.

A superconductor is also utilized as a magnet for confining plasma in nuclear fusion reactors. As an example of a method for utilizing a superconductor in a nuclear fusion reactor, the use of a superconductor as a material for constituting a toroidal magnetic field coil in a nuclear fusion reactor including a toroidal plasma chamber with a central column is known (for example, Patent Document 2). The toroidal magnetic field coil is a coil generating a magnetic field to confine plasma.

High economic efficiency is required to establish a nuclear fusion reactor as a practical power plant. When a superconductor is utilized in a nuclear fusion reactor, it needs to be maintained at a temperature indicating a superconductive state. For this reason, the costs of the superconductor accounts for a high proportion. A cooling means is used in order to maintain the temperature of a superconductor equal to or lower than a transition temperature. Patent Document 2 describes, although it does not mention any specific material for a toroidal magnetic field coil, the use of a high-temperature superconductor (HTS) coil having a high transition temperature.

The International Thermonuclear Experimental Reactor (ITER) project specifies the use of Nb₃Sn superconducting strands as materials for high-performance high-quality superconducting wires in order to realize a magnetic confinement nuclear fusion reactor (for example, Non-Patent Document 1).

### CITATION LIST

### Patent Documents

Patent Document 1: PCT International Publication No. WO2013/154187

Patent Document 2: Published Japanese Translation No. 2016-534327 of the PCT international publication

### Non-Patent Document

Non-Patent Document 1: Takaaki ISONO (1997). “Development of Nb₃Sn Strands for the International Thermonuclear Experimental Reactor (ITER) in Japan”, p. 150-157

### SUMMARY OF INVENTION

### Technical Problem

As is well known, nuclear fusion reactors utilize nuclear fusion reactions generating He and neutrons through nuclear fusion of deuterium and tritium. For this reason, in nuclear fusion reactors, high irradiation resistance is required for a toroidal magnetic field coil due to generation of neutron beams. However, in the Nb:Sn superconductors disclosed in Patent Document 1 and Non-Patent Document 1, the transition temperature after irradiation with heavy quantum beams, such as neutrons, or high-energy particles falls compared to that before irradiation.

In Patent Document 2, no specific material is described as a superconductor. Against such a background of the technology in the related art, it is desired to seek for a high-temperature superconductor with a small decrease in transition temperature from before irradiation to after irradiation.

The present invention has been made in consideration of the foregoing circumstances, and an object thereof is to provide a high-temperature superconductor and a method for manufacturing it exhibiting small decrease in transition temperature from before irradiation to after irradiation with high-energy particles.

### Solution to Problem

In order to resolve the foregoing problems, the present invention provides the following means.

A superconductor according to an aspect of the present invention is represented by General Formula (1).

REBA₂Cu₃O_{7-δ} (1)

(in Formula (1), RE is composed of Y, Gd, and X, X is composed of one or multiple species of elements selected from the group consisting of La, Ce, Pr, Nd, Sm, Eu, Tb, Dy, Ho, Er, Tm, Yb, and Lu, and 0≤δ≤1)

In the superconductor according to the foregoing [1], in the foregoing Formula (1), X may be composed of Dy and one or multiple species of elements selected from the group consisting of La, Ce, Pr, Nd, Sm, Eu, Tb, Ho, Er, Tm, Yb, and Lu.

In the superconductor according to the foregoing [1] or [2], five or more species of rare earth elements may be contained therein, and a mixing entropy ΔSₘᵢₓ of an RE site may be 1.5R or greater (R is a gas constant).

In the superconductor according to any one of the foregoing [1] to [3], in the foregoing Formula (1), RE may be represented by General Formula (2).

YₐGd_{b}X_{c} (2)

(0.05≤a≤0.9, 0.05≤b≤0.9, and 0.05≤c≤0.9)

A method for manufacturing a superconductor according to another aspect of the present invention has a preparation step of preparing a base layer having a surface constituted of single crystal, and a vapor deposition step of vapor-depositing a superconductor on the base layer. In the vapor deposition step, a target represented by General Formula (1) is used.

REBa₂Cu₃O_{7-δ} (1)

(in Formula (1), RE is composed of Y, Gd, and X, X is composed of one or multiple species of elements selected from the group consisting of La, Ce, Pr, Nd, Sm, Eu, Tb, Dy, Ho, Er, Tm, Yb, and Lu, and 0≤δ≤1)

In the method for manufacturing a superconductor, in the foregoing [5], in the vapor deposition step, the target may be disposed at a position facing the base layer, and the target may be irradiated with a pulsed laser.

### Advantageous Effects of Invention

According to the present invention, it is possible to provide a high-temperature superconductor and a method for manufacturing it exhibiting small decrease in transition temperature from before irradiation to after irradiation with high-energy particles.

### BRIEF DESCRIPTION OF DRAWINGS

FIG. 1 A schematic view showing an example of a crystal structure of a superconductor according to an embodiment of the present invention.

FIG. 2 A partial cross-sectional perspective view of a superconducting wire according to the embodiment of the present invention.

FIG. 3 An explanatory view of a constitution of a superconducting laminate provided in the superconducting wire in FIG. 2.

FIG. 4 An explanatory view of a method for manufacturing a superconductor according to another embodiment of the present invention, the view shows a state in which a vapor deposition step is performed by a PLD method.

FIG. 5 A graph showing temperature dependency of magnetization before and after a superconductor of Example 1 is irradiated with He ions. FIG. 5(a) shows temperature dependency of magnetization at 0 to 120 K, and FIG. 5(b) shows a part in the vicinity of a transition temperature T_{c} in FIG. 5(a) in an enlarged manner.

FIG. 6 A graph showing temperature dependency of magnetization before and after a superconductor of Example 2 is irradiated with He ions. FIG. 6(a) shows temperature dependency of magnetization at 0 to 120 K, and FIG. 6(b) shows a part in the vicinity of the transition temperature T_{c} in FIG. 6(a) in an enlarged manner.

FIG. 7 A graph showing temperature dependency of magnetization before and after a superconductor of Example 3 is irradiated with He ions. FIG. 7(a) shows temperature dependency of magnetization at 0 to 120 K, and FIG. 7(b) shows a part in the vicinity of the transition temperature T_{c} in FIG. 7(a) in an enlarged manner.

FIG. 8 A graph showing temperature dependency of magnetization before and after a superconductor of Comparative Example 1 is irradiated with He ions.

FIG. 9 A graph showing temperature dependency of magnetization before and after a superconductor of Comparative Example 2 is irradiated with He ions. FIG. 9(a) shows temperature dependency of magnetization at 0 to 120 K, and FIG. 9(b) shows a part in the vicinity of the transition temperature T_{c} in FIG. 9(a) in an enlarged manner.

FIG. 10 A graph showing critical current densities before and after a sample of Example 1 is irradiated with He ions. FIG. 10(a) is a graph before irradiation with He ions, and FIG. 10(b) is a graph after irradiation with He ions.

FIG. 11 A graph showing critical current densities before and after a sample of Example 2 is irradiated with He ions. FIG. 11(a) is a graph before irradiation with He ions, and FIG. 11(b) is a graph after irradiation with He ions.

FIG. 12 A graph showing critical current densities before a sample of Example 3 is irradiated with He ions. FIG. 12(a) is a graph before irradiation with He ions, and FIG. 12(b) is a graph after irradiation with He ions.

FIG. 13 A graph showing critical current densities before and after a sample of Comparative Example 1 is irradiated with He ions. FIG. 13(a) is a graph before irradiation with He ions, and FIG. 13(b) is a graph after irradiation with He ions.

FIG. 14 A graph showing critical current densities before and after a sample of Comparative Example 2 is irradiated with He ions. FIG. 14(a) is a graph before irradiation with He ions, and FIG. 14(b) is a graph after irradiation with He ions.

FIG. 15 A graph showing critical current densities before and after a sample of Comparative Example 3 is irradiated with He ions. FIG. 15(a) is a graph before irradiation with He ions, and FIG. 15(b) is a graph after irradiation with He ions.

### DESCRIPTION OF EMBODIMENT

Hereinafter, an example of an embodiment of the present invention will be described in detail with reference to the drawings. In the drawings used in the following description, in order to make characteristics of the present invention easy to understand, characteristic parts may be shown in an enlarged manner for the sake of convenience. For this reason, dimensional ratios or the like of each constituent element may differ from actual values thereof.

### Superconductor

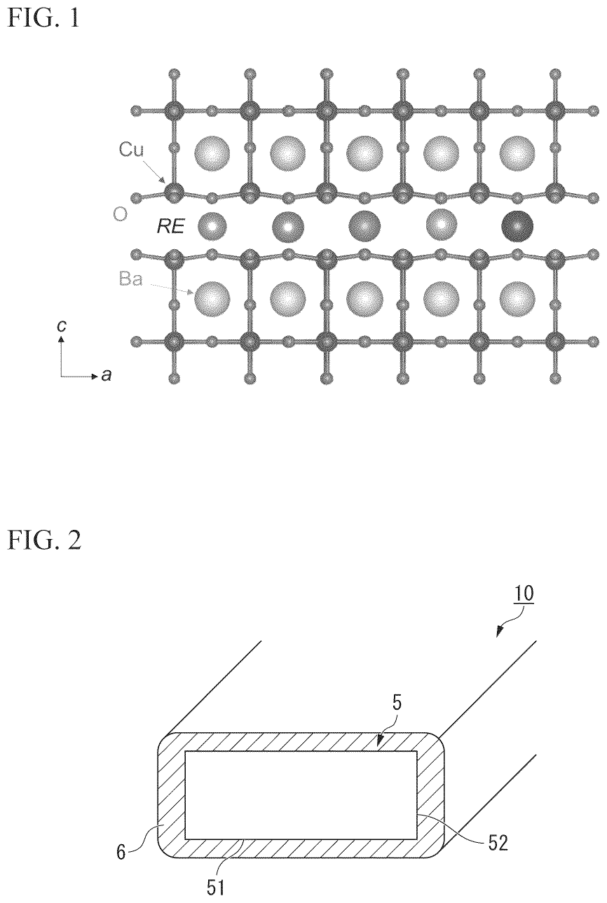

FIG. 1 is a schematic view showing an example of a crystal structure of a superconductor according to the embodiment of the present invention.

The superconductor according to the embodiment of the present invention is a superconductor represented by General Formula (1).

REBa₂Cu₃O_{7-δ} (1)

In Formula (1), RE represents a rare earth metal element. Atomic sites of rare earth elements RE are indicated by the reference sign RE in FIG. 1. In the superconductor according to the embodiment of the present invention, three or more species of rare earth elements, Y (yttrium), Gd (gadolinium), and X, are present at the atomic sites of the rare earth elements RE. X is one or more species of rare earth element selected from the group consisting of La (lanthanum), Ce (cerium), Pr (praseodymium), Nd (neodymium), Sm (samarium), Eu (europium), Tb (terbium), Dy (dysprosium), Ho (holmium), Er (erbium), Tm (thulium), Yb (ytterbium), and Lu (lutetium). In Formula (1), δ represents the oxygen deficit amount. δ is within a range of 0≤δ≤1 and is preferably within a range of 0≤δ0.6. In such a superconductor, even if it is irradiated with high-energy particles, its superconducting transition temperature does not decrease much.

In the foregoing Formula (1), RE may be represented by General Formula (2).

YₐGd_{b}X_{c} (2)

(0.05≤a≤0.9, 0.05≤b≤0.9, and 0.05≤c≤0.9)

In Formula (1), in addition to Y and Gd, the rare earth elements RE preferably include at least either Dy or Yb. That is, the rare earth elements RE preferably include Y, Gd, and Dy, include Y, Gd, and Yb, or include Y, Gd, Dy, and Yb. In a superconductor in which the rare earth elements RE include Y, Gd, and Dy, X is composed of Dy and one or multiple species of elements selected from the group consisting of La, Ce, Pr, Nd, Sm, Eu, Tb, Ho, Er, Tm, Yb, and Lu. In a superconductor in which the rare earth elements RE include Y, Gd, and Yb, X is composed of Yb and one or multiple species of elements selected from the group consisting of La, Ce, Pr, Nd, Sm, Eu, Tb, Ho, Er, Tm, and Lu. In a superconductor in which the rare earth elements RE include Y, Gd, Dy, and Yb, in addition to Dy and Yb, X may or may not include an element selected from the group consisting of La, Ce, Pr, Nd, Sm, Eu, Tb, Ho, Er, Tm, and Lu.

The superconductor of the present embodiment is preferably a high-entropy superconductor whose mixing entropy ΔSₘᵢₓ at the atomic sites of the rare earth elements RE is 1.1R or greater, preferably 1.39R or greater, and more preferably 1.5R or greater. Here, R represents the gas constant. In a high-entropy superconductor whose mixing entropy ΔSₘᵢₓ is 1.5R or greater, for example, five or more kinds of rare earth elements are present at the atomic sites of the rare earth elements RE. Examples of such a superconductor include those containing Y, Gd, Dy, Ho, and Yb as the rare earth elements RE. It has been confirmed that such a superconductor exhibits a high critical current density even after being irradiated with high-energy particles, and that its superconducting transition temperature does not decrease much due to the irradiation. A superconductor containing Y, Gd, Dy, Ho, and Yb as the rare earth elements RE and having a general formula represented by Formula (1) contains five or more species of rare earth elements and may contain one or more species selected from the group consisting of La, Ce, Pr, Nd, Sm, Eu, Tb, Er, Tm, and Lu in addition to the foregoing rare earth elements. Such a high-entropy superconductor containing Y, Gd, and Dy exhibits a high transition temperature T_{c} and a high critical current density Je even after irradiation with high-energy particles. The critical current density Je is a critical current value per unit area of a superconductor.

In addition, it is preferable to avoid using a superconductor having a long half-life when they are radioactive, assuming that they may be used in superconducting magnets for nuclear fusion reactors. Among the foregoing X elements, Sm and Eu have a longer half-life than other X elements when they are radioactive. For this reason, the foregoing X elements are preferably elements other than Sm and Eu, that is, one or more species selected from the group consisting of Dy, La, Ce, Pr, Nd, Tb, Ho, Er, Tm, Yb, and Lu.

The superconductor according to the present embodiment contains three or more species of rare earth elements RE and exhibits a high mixing entropy ΔSₘᵢₓ at the atomic sites of the rare earth elements RE. In addition, due to the high mixing entropy ΔSₘᵢₓ , a solid solution is likely to be formed. Therefore, the superconductor according to the present embodiment exhibits high structural stability, heat resistance, and acid resistance. Moreover, as described above, since the superconductor according to the present embodiment has Y element, Gd element, and the X elements that are different rare earth elements, even when it is used in a nuclear fusion reactor or the like which is irradiated with heavy quantum beams, such as neutrons, or high-energy particles, decrease in transition temperature from before irradiation to after irradiation with high-energy particles can be reduced. That is, according to the present embodiment, a superconductor exhibiting excellent irradiation resistance with respect to the transition temperature can be realized. Therefore, according to the superconductor of the present embodiment, a cooling means for maintaining the temperature at which the superconductor functions can be simplified or energy required for cooling can be reduced.

### Superconducting Wire

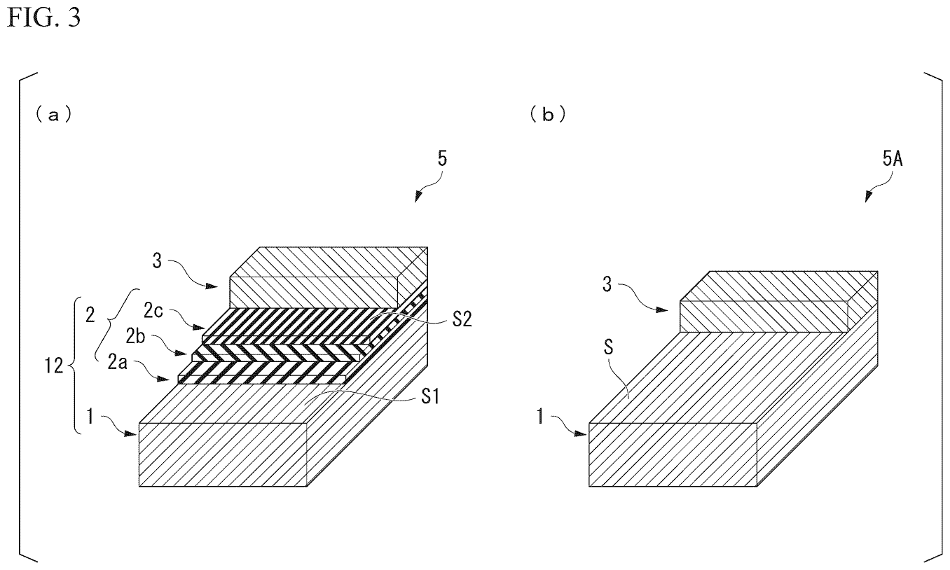

FIG. 2 is a partial cross-sectional perspective view of a superconducting wire according to the embodiment of the present invention. FIG. 3 is an explanatory view of a constitution of a superconducting laminate provided in the superconducting wire in FIG. 2. For the sake of convenience, FIG. 3 shows the end portion of each layer offset from each of others. The structures of the superconductor and the superconducting laminate according to the present embodiment are not limited to the structures shown in the diagram.

A superconducting wire 10 shown in FIG. 2 includes a superconducting laminate 5 and a stabilization layer 6. The stabilization layer 6 extends along the superconducting laminate 5 and is provided in a manner of coming into contact with a main surface 51 and a side surface 52 thereof. The stabilization layer 6 is formed in a manner of surrounding the superconducting laminate 5. The stabilization layer 6 functions as a bypass unit which is generated when a superconducting layer included in the superconducting laminate 5 (which will be described below in detail) transfers to a normal conducting state, and which commutates a current.

The stabilization layer 6 is, for example, made of a metal such as copper, a copper alloy, aluminum, an aluminum alloy, or silver. Examples of a copper alloy which can be used for the stabilization layer 6 include a Cu—Zn alloy and a Cu—Ni alloy. The thickness of the stabilization layer 6 is several um to 300 μm, for example. The stabilization layer 6 can be formed by plating (for example, electrolytic plating).

The superconducting laminate 5 shown in FIG. 3(A) includes a substrate 1, an intermediate layer 2, and a superconducting layer 3. The substrate 1 is, for example, formed of a metal. For example, the substrate 1 is made of a nickel alloy; stainless steel; or an orientated Ni—W alloy in which an aggregate structure is introduced into nickel steel. The thickness of the substrate 1 is 10 to 500 μm, for example. The intermediate layer 2 is preferably provided on a main surface S1 of the substrate 1, but the intermediate layer 2 can be omitted. FIG. 3(B) is a perspective view of a superconducting laminate according to a modification example of the superconducting laminate shown in FIG. 3(A). In a superconducting laminate 5A shown in FIG. 3(B), the intermediate layer 2 is not provided, and the superconducting layer 3 is directly formed on the substrate 1. As shown in FIG. 3(A), in the superconducting laminate 5 in which the substrate 1, the intermediate layer 2, and the superconducting layer 3 are formed in this order, the substrate 1 and the intermediate layer 2 will be collectively referred to as a base layer 12, and the intermediate layer 2 shown in FIG. 3(B) is omitted. In the superconducting laminate 5A in which the superconducting layer 3 is formed in a manner of coming into contact with the substrate 1 and the substrate 1, the substrate 1 will be referred to as a base layer.

The intermediate layer 2 is provided between the substrate 1 and the superconducting layer 3. The intermediate layer 2 is, for example, constituted of a plurality of layers. FIG. 3 shows an example in which the intermediate layer 2 includes a first layer 2a, a second layer 2b, and a third layer 2c in this order from the side close to the substrate 1. The intermediate layer 2, for example, has a bed layer, an orientation layer, a cap layer, and the like as a plurality of layers each having a different function. In the intermediate layer 2, for example, the surface on the superconducting layer 3 side and a part in the vicinity of it are constituted of single crystal.

The first layer 2a is, for example, a bed layer. The bed layer serves to reduce reactions at the interface between the substrate 1 and the superconducting layer 3 and improve the orientation of the layer formed thereon. Examples of the material of the bed layer include CeO₂, Er₂O₃, Y₂O₃, Dy₂O₃, Eu₂O₃, Ho₂O₃, and La₂O₃.

The second layer 2b is, for example, an orientation layer. The orientation layer is provided to control the crystal orientation of a cap layer when the cap layer is formed thereon. The cap layer is, for example, formed of metal oxides such as Gd₂Zr₂O₇, MgO, ZrO₂—Y₂O₃ (YSZ), SrTiO₃, CeO₂, Y₂O₃, Al₂O₃, Gd₂O₃, Zr₂O₃, Ho₂O₃, or Nd₂O₃. It is preferable to use an orientation layer formed by an ion beam assisted deposition (IBAD) method.

The third layer 2c is, for example, a cap layer. The cap layer is subjected to film formation on the surface of the orientation layer and made of a material allowing crystal grains to self-orient in the in-plane direction. The cap layer is, for example, formed of CeO₂, Y₂O₃, Al₂O₃, Gd₂O₃, ZrO₂, YSZ, Ho₂O₃, Nd₂O₃, or LaMnO₃.

The superconducting layer 3 is formed on a surface S2 of the intermediate layer 2 farthest from the substrate 1. The thickness of the superconducting layer 3 is 0.5 μm to 10 μm, for example.

The superconducting layer 3 is constituted of the superconductor according to the foregoing embodiment. That is, the superconducting layer 3 is constituted of a superconductor represented by General Formula (1).

REBa₂Cu₃O_{7-δ} (1)

In Formula (1), RE is composed of Y, Gd, and X, X is composed of one or multiple species of elements selected from the group consisting of La, Ce, Pr, Nd, Sm, Eu, Tb, Dy, Ho, Er, Tm, Yb, and Lu, and 0≤δ≤1 is satisfied.

FIG. 3(a) shows the superconducting laminate 5 in which the base layer 12 includes the substrate 1 and the intermediate layer 2. However, the superconducting laminate 5 according to the present embodiment may be a layer constituted using a single material, as long as the surface and a part in the vicinity thereof are constituted of a single crystal. That is, the base layer 12 may be constituted of one layer. FIG. 3(b) shows a constitution, as an example, in which the base layer 12 is constituted of one layer. In the superconducting laminate 5A, the substrate 1 is a layer constituted of a single material, in which a surface S and a part in the vicinity of it are constituted of single crystal. For example, the base layer may be constituted of a single crystal SrTiO₃ substrate or a single crystal MgO substrate. That is, in the superconducting laminate 5A, the substrate 1 is, for example, a single crystal SrTiO₃ substrate or a single crystal MgO substrate.

The superconducting wire 10 is wound to form a coil. The coil according to the embodiment of the present invention is, for example, a toroidal magnetic field coil generating a magnetic field for confining plasma in a nuclear fusion reactor. The coil according to the present embodiment is, for example, a multilayer-wound coil in which a superconducting wire is wound around a winding core a plurality of times. The coil according to the present embodiment is produced by winding a superconducting wire around a winding core.

### Method for Manufacturing Superconductor

Hereinafter, an example of a method for manufacturing the superconductor according to the foregoing embodiment will be described. The method for manufacturing the superconductor according to the embodiment of the present invention has a preparation step of preparing the base layer 12 having a surface constituted of a single crystal, and a vapor deposition step of vapor-depositing a superconductor on the base layer 12. In the method for manufacturing the superconductor according to the present embodiment, in the vapor deposition step, a target represented by the following General Formula (1) is used.

REBa₂Cu₃O_{7-δ} (1)

(in Formula (1), RE is composed of Y, Gd, and X, X is composed of one or multiple species of elements selected from the group consisting of La, Ce, Pr, Nd, Sm, Eu, Tb, Dy, Ho, Er, Tm, Yb, and Lu, and 0≤δ≤1 is satisfied)

Hereinafter, the method for manufacturing a superconductor will be described using a method for manufacturing a superconducting laminate as an example, but the structure of the superconductor to be manufactured is not limited to the structure of the superconducting laminate.

### Preparation Step

First, the base layer 12 having a surface constituted of single crystal is prepared. The base layer 12 is, for example, constituted of only the substrate 1 or the substrate 1 and the intermediate layer 2. FIG. 3 shows an example in which the base layer 12 is constituted of the substrate 1 and the intermediate layer 2 which is formed on the substrate 1, but it is not limited to this example, and the intermediate layer 2 can be omitted. For example, the intermediate layer 2 can be formed by performing a physical vapor deposition method such as a PLD method, a vapor deposition method such as a chemical vapor deposition method, or firing with respect to the substrate 1. For example, in the preparation step, processing is performed such that at least one surface of the base layer 12 and a part in the vicinity of it are constituted of single crystal. For example, the preparation step is performed a predetermined number of times in stages in accordance with the number of intermediate layers 2 to be formed.

### Target Preparation Step

Next, a target to be used in the vapor deposition step is prepared. The target is a composite having a composition corresponding to that of a desired superconductor. The composition of a composite constituting the target is, for example, the same as the composition of the superconductor to be produced. For example, the target is a polycrystal having the same composition as the superconductor to be produced. For example, the target is produced by mixing simple substances or oxides of predetermined metal elements in a predetermined ratio and firing the mixture. In the present embodiment, in order to produce a superconductor which essentially contains at least Y and Gd as the rare earth elements RE and further has one or more species of different rare earth elements as the X elements, three or more species of simple substances or oxides of rare earth elements are mixed. It is preferable to mix four or more species, and it is more preferable to mix five or more species. The firing for producing the target may be performed once or may be performed a plurality of times in stages.

### Vapor Deposition Step

Next, the superconductor is subjected to vapor deposition on the base layer 12. The vapor deposition step is, for example, performed by a pulsed laser deposition (PLD) method, or a physical vapor deposition (PVD) method such as molecular beam epitaxy (MBE) or a sputtering method. In the vapor deposition step, it is preferable that a target T be disposed at a position facing the base layer 12 and the target T be irradiated with a laser.

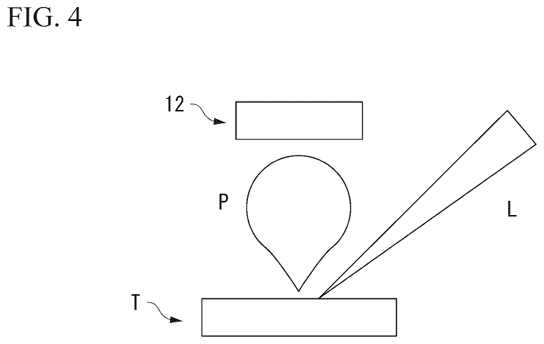

FIG. 4 is an explanatory view of a method for manufacturing a superconductor according to another embodiment of the present invention, and the view shows a state in which the vapor deposition step is performed by the PLD method. The PLD method with reference to FIG. 4 will be described. The PLD method is performed using a PLD device. The target T and the base layer 12 are installed in a manner facing each other inside a chamber of a PLD device. The atmosphere inside the chamber can be the air atmosphere, for example. The vapor deposition step is, for example, performed by heating the base layer 12 while adjusting the pressure inside the chamber to a low oxygen partial pressure.

The oxygen partial pressure inside the chamber is, for example, 1×10⁻⁵ Pa or higher and 50 Pa or less and is preferably 1 Pa or higher and 20 Pa or less. The temperature (set temperature) of the base layer is, for example, set to be 200 °C or higher and 1,000 °C or less.

The PLD device irradiates the target T with laser light L and condenses the laser light L on the surface of the target T using a condensing lens or the like. A pulsed laser is used as the laser light L for irradiating the target T. The laser density is set to 0.1 J/cm² or higher and 5 J/cm² or less, for example.

Constituent particles of the target T are knocked out or evaporated by condensing a laser on the surface of the target T, thereby generating a plume P. When the constituent particles of the target T included in the plume P are deposited on the surface of the base layer 12, a thin film constituted of the constituent particles of the target T is formed on the surface of the base layer 12. Therefore, the composition of the thin film formed on the base layer 12 can be changed by changing the composition of the constituent particles of the target T. That is, when a superconductor having a desired composition is formed on the base layer 12, the target T having the same composition as the desired superconductor may be used.

Therefore, the target T represented by the foregoing Formula (1) can be used. In Formula (1), the elements X in the rare earth elements RE preferably include Dy and one or multiple species of elements selected from the group consisting of La, Ce, Pr, Nd, Sm, Eu, Tb, Ho, Er, Tm, Yb, and Lu and is more preferable to be constituted of these elements.

In Formula (1), δ represents the oxygen deficit amount. δ is within a range of 0δ≤1.

In the foregoing Formula (1), RE may be represented by General Formula (2).

YₐGd_{b}X_{c} (2)

(0.05≤a≤0.9, 0.05≤b≤0.9, and 0.05≤c≤0.9)

In Formula (1), in addition to Y and Gd, the rare earth elements RE preferably include at least either Dy or Yb. That is, the rare earth elements RE preferably include Y, Gd, and Dy, include Y, Gd, and Yb, or include Y, Gd, Dy, and Yb.

In order to produce a superconductor containing five or more species of rare earth elements, the target T preferably contains five or more species of rare earth elements. For example, in order to produce a superconductor containing Y, Gd, Dy, Ho, and Yb as the rare earth elements RE, the target T preferably contains Y, Gd, Dy, Ho, and Yb. A superconductor formed using such a target has a high mixing entropy, and the critical current density becomes high even after irradiation with high-energy particles.

In addition, from the viewpoint of curbing elongation of the half-life when a formed superconductor is radioactive, the X elements contained in the target T and having a composite represented by Formula (1) are preferably elements other than Sm and Eu, that is, one or more species selected from the group consisting of Dy, La, Ce, Pr, Nd, Tb, Ho, Er, Tm, Yb, and Lu.

After a superconducting layer constituted of a superconductor is formed on the base layer 12, it is subjected to furnace cooling, and a superconducting laminate taken out. When furnace cooling is performed, the oxygen partial pressure can be set to a higher value than the oxygen partial pressure during film formation of the superconductor thin film. For example, the oxygen partial pressure during furnace cooling can be set to be equivalent to the oxygen partial pressure in the atmosphere.

According to the method for manufacturing the superconductor of the present embodiment, it is possible to form a superconducting wire in which the superconductor according to the foregoing embodiment is formed as a thin film. In the foregoing example, the method for forming a superconducting wire has been described. However, in the method for manufacturing a thin film constituted of a superconductor, a single crystal substrate constituted of simply one layer may be prepared as the base layer 12 and subjected to vapor deposition, and the base layer 12 having a plurality of layers does not have to be used.

Throughout the entirety of the present disclosure, the singular-term expressions should be understood to include its plural concept unless otherwise stated. Therefore, the singular articles (for example, “a”, “an”, “the”, and the like in English) should be understood to include its plural concept unless otherwise stated.

### EXAMPLE

### Example 1

Hereinafter, examples of the present invention will be described. The present invention is not limited to only the following examples.

First, a base layer was prepared. A strontium titanate (SrTIO₃) single crystal substrate was prepared as a substrate.

Next, a target was prepared. In preparing the target, first, regarding the material of the target, Y₂O₃ (purity 99.9%), Gd₂O (purity 99.9%), Dy₂O₃ (purity 99.9%), BaCO₃ (purity 98%), and CuO (purity 99.9%) were weighed in a mass ratio of 1/3:1/3:1/3:2:3 and mixed in a mortar, and a mixed powder was prepared.

Next, the mixed powder was transferred to a crucible, heated at 930 °C for 20 hours as primary firing (pre-firing), and subjected to furnace cooling to room temperature.

Next, the mixed powder after pre-firing was mixed in an agate mortar and pressure-molded into a pellet shape. Next, as secondary firing, the pellet-shaped mixed powder was heated at 930 °C for 8 hours, subsequently heated at 300 °C for 18 hours, and subjected to furnace cooling to room temperature.

Next, the base layer and the target were installed inside a chamber such that they faced each other. Next, vacuuming was performed using a rotary pump until the oxygen partial pressure inside the chamber reached 10 Pa. The base layer was heated using a heater until the set temperature reached 920 °C. After the base layer reached the set temperature, it was left alone for 10 minutes for stabilization.

In order to remove impurities on the surface of the target, a shutter was closed and the target was rotated and revolved to perform pre-ablation. Next, the shutter was opened and the laser energy density was set to 1.3 J/cm² to perform film formation. During the film formation, while oxygen was introduced into the chamber, the exhaust amount of the valve was adjusted to maintain the oxygen partial pressure inside the chamber at 1×10¹ Pa.

After the film formation ended, the power source of the heater was turned off, and the temperature of the base layer was lowered while maintaining the oxygen partial pressure. After the temperature of the base layer reached 450 °C, the base layer was subjected to furnace cooling to room temperature at the oxygen partial pressure of 2×10⁴ Pa for 90 minutes. In this manner, a superconducting laminate in which a superconducting layer constituted of a superconductor represented by the composition formula Y_{1/3}Gd_{1/3}Dy_{1/3}Ba₂Cu₃O_{7-δ} was formed on a base layer constituted of a substrate and an intermediate layer was produced.

### Example 2

Except that the target was changed, a superconducting laminate in which a superconducting layer constituted of a superconductor represented by the composition formula Y_{0.25}Gd_{0.25}Dy_{0.25}Ho_{0.25}Ba₂Cu₃O_{7-δ} was formed on the base layer was produced by a method similar to that of Example 1.

In Example 2, the target was prepared in the following procedure. In preparing the target, first, regarding the material of the target, Y₂O₃ (purity 99.9%), Gd₂O₃ (purity 99.9%), Dy₂O₃ (purity 99.9%), Ho₂O₃ (purity 99.9%), BaCO₃ (purity 98%), and CuO (purity 99.9%) were weighed in a mass ratio of 1/4:1/4:1/4:1/4:2:3 and mixed in a mortar, and a mixed powder was prepared. The firing conditions for producing the target using the mixed powder were similar to those in Example 1.

### Example 3

Except that the target was changed, a superconducting laminate in which a superconducting layer constituted of a superconductor represented by the composition formula Y_{0.2}Gd_{0.2}Dy_{0.2}Ho_{0.2}Yb_{0.2}Ba₂Cu₃O_{7-δ} was formed on the base layer was produced by a method similar to that of Example 1.

In Example 3, the target was prepared in the following procedure. In preparing the target, first, regarding the material of the target, Y₂O₃ (purity 99.9%), Gd₂O₃ (purity 99.9%), Dy₂O₃ (purity 99.9%), Ho₂O₃ (purity 99.9%), Yb₂O₃ (purity 99.9%), BaCO₃ (purity 98%), and CuO (purity 99.9%) were weighed in a mass ratio of 1/5:1/5:1/5:1/5:1/5:2:3 and mixed in a mortar, and a mixed powder was prepared. The firing conditions for producing the target using the mixed powder were similar to those in Example 1.

### Comparative Example 1

Except that the target was changed, a superconducting laminate in which a superconducting layer constituted of a superconductor represented by the composition formula YBa₂Cu₃O_{7-δ} was formed on the base layer was produced by a method similar to that of Example 1.

In Comparative Example 1, the target was prepared in the following procedure. In preparing the target, first, regarding the material of the target, Y₂O₃ (purity 99.9%), BaCO₃ (purity 98%), and CuO (purity 99.9%) were weighed in a mass ratio of 1:2:3 (mol) and mixed in a mortar, and a mixed powder was prepared. The firing conditions for producing the target using the mixed powder were similar to those in Example 1.

### Comparative Example 2

Except that the target was changed, a superconducting laminate in which a superconducting layer constituted of a superconductor represented by the composition formula Y_{0.25}Sm_{0.25}Eu_{0.25}Dy_{0.25}Ba₂Cu₃O_{7-δ} was formed on the base layer was produced by a method similar to that of Example 1.

In Comparative Example 2, the target was prepared in the following procedure. In preparing the target, first, regarding the material of the target, Y₂O₃ (purity 99.9%), Sm₂O₃ (purity 99.9%), Eu₂O₃ (purity 99.9%), Dy₂O₃ (purity 99.9%), BaCO₃ (purity 98%), and CuO (purity 99.9%) were weighed in a mass ratio of 1/4:1/4:1/4:1/4:2:3 (mol) and mixed in a mortar, and a mixed powder was prepared. The firing conditions for producing the target using the mixed powder were similar to those in Example 1.

### Evaluation of Irradiation Resistance Relevant to Superconducting Transition Temperature

With respect to the superconducting laminates of Examples 1 to 3, Comparative Example 1, and Comparative Example 2, the temperature dependency of magnetization of the superconductor was measured using a magnetic property measurement system (MPMS-3). Next, the superconductors of Examples 1 to 3 and Comparative Example 1 were irradiated with He ions having approximately the same energy (1 MeV) as neutron beams. Next, with respect to the superconductors after irradiation, the temperature dependency of magnetization was measured again. The superconducting transition temperatures T_{c} before and after the superconductors of Examples 1 to 3 were irradiation with high-energy He ions were confirmed, and the irradiation resistance was evaluated. The superconducting transition temperature T_{c} was evaluated as the temperature at which the magnetization starts to fall during zero field cooling (ZFC).

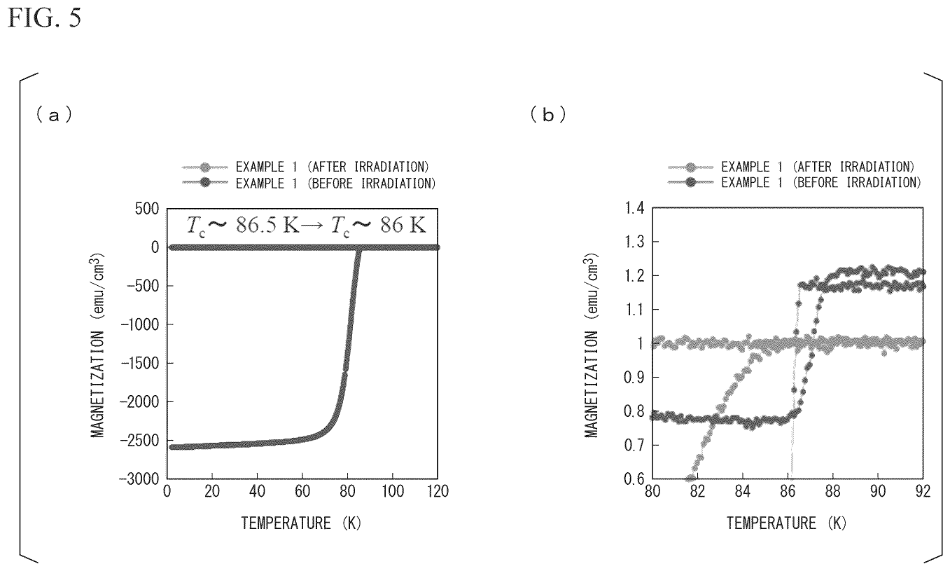

FIG. 5(a) is a graph showing temperature dependency of magnetization before and after the superconductor of Example 1 is irradiated with He ions, and FIG. 5(b) is an enlarged view of a part in the vicinity of the transition temperature T_{c} in FIG. 5(a). As shown in FIG. 5(a) and 5(b), in the superconductor of Example 1, the superconducting transition temperature T_{c} before irradiation with He ions was 86.5 K, whereas the superconducting transition temperature after irradiation with He ions was 86 K. Hereinafter, in the graphs showing the temperature dependency of the time before irradiation with He ions, there are some areas where the graphs overlap and one graph may be partially or entirely invisible. Therefore, in order to deal with such cases, an enlarged view of a part in the vicinity of the transition temperature T_{c} is also shown.

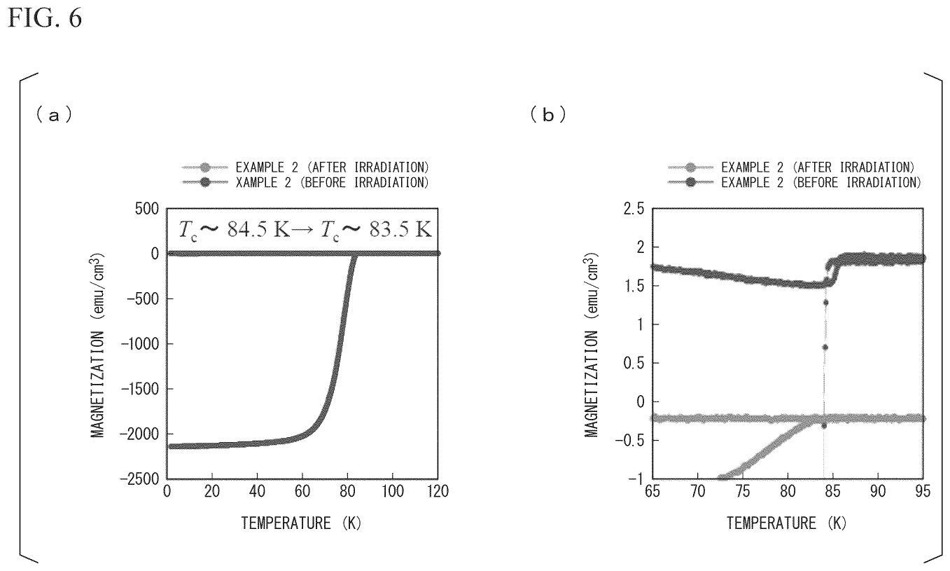

FIG. 6(a) is a graph showing temperature dependency of magnetization before and after the superconductor of Example 2 is irradiated with He ions, and FIG. 6(b) is an enlarged view of a part in the vicinity of the transition temperature T_{c} in FIG. 6(a). As shown in FIG. 6(a) and 6(b), in the superconductor of Example 2, the superconducting transition temperature T_{c} before irradiation with He ions was 84.5 K, whereas the superconducting transition temperature after irradiation with He ions was 83.5 K.

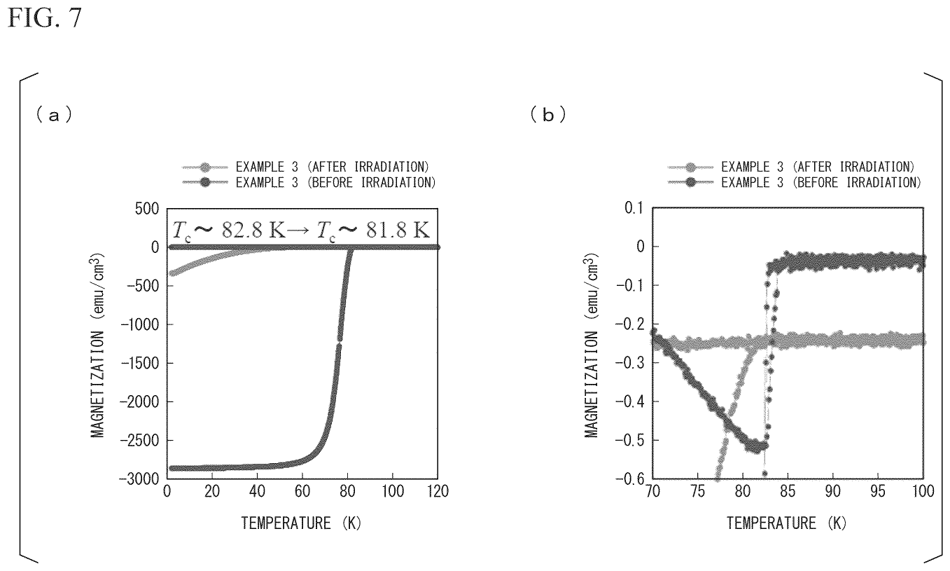

FIG. 7(a) is a graph showing temperature dependency of magnetization before and after the superconductor of Example 3 is irradiated with He ions, and FIG. 7(b) is an enlarged view of a part in the vicinity of the transition temperature T_{c} in FIG. 7(a). As shown in FIG. 7(a) and 7(b), in the superconductor of Example 3, the superconducting transition temperature T_{c} before irradiation with He ions was 82.8K, whereas the superconducting transition temperature after irradiation with He ions was 81.8 K.

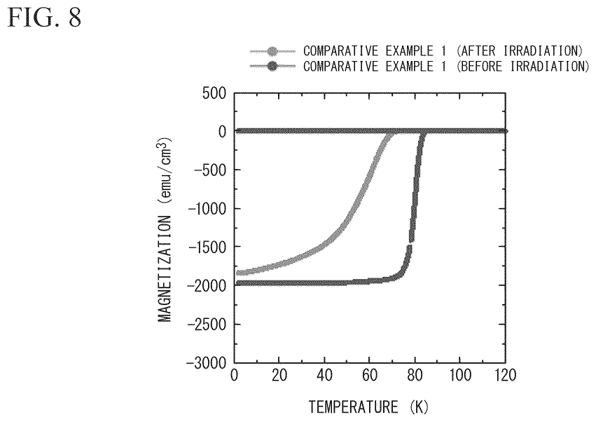

FIG. 8 is a graph showing temperature dependency of magnetization before and after the superconductor of Comparative Example 1 is irradiated with He ions. As shown in FIG. 8, in the superconductor of Comparative Example 1, the superconducting transition temperature T_{c} before irradiation with He ions was 86 K, whereas the superconducting transition temperature after irradiation with He ions was 73.0 K.

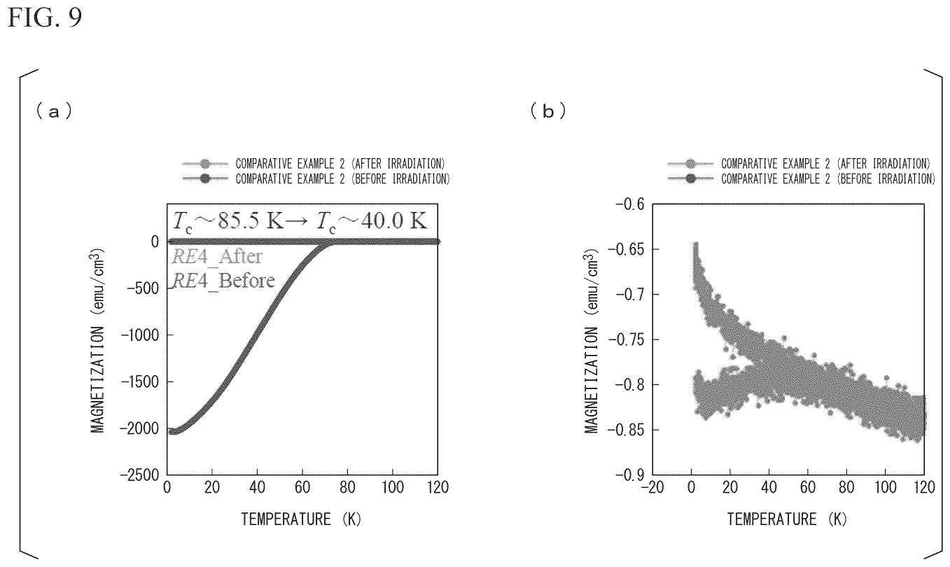

FIG. 9(a) is a graph showing temperature dependency of magnetization before and after the superconductor of Comparative Example 2 is irradiated with He ions, and FIG. 9(b) is an enlarged view of a part in the vicinity of the transition temperature Tc in FIG. 9(a). As shown in FIG. 9(a) and 9(b), in the superconductor of Comparative Example 2, the superconducting transition temperature T_{c} before irradiation with He ions was 85.5 K, whereas the superconducting transition temperature after irradiation with He ions was 40.0 K.

It was confirmed that, as shown in FIGS. 8, 9(a), and 9(b), the superconducting transition temperature decreased by 13 K due to irradiation with high-energy He ions in the superconductor of Comparative Example 1 and the superconducting transition temperature decreased by 45.5 K due to irradiation with high-energy He ions in the superconductor of Comparative Example 2, whereas as shown in FIG. 5(a) to 7(b), decrease in superconducting transition temperature due to irradiation with high-energy He ions was 1 K or smaller in the superconductors of Examples 1 to 3, which were high-temperature superconductors having exceptional irradiation resistance. Meanwhile, in the superconductor of Comparative Example 1, since the transition temperature after irradiation with high-energy He ions decreased significantly, it was found that the function as a high-temperature superconductor deteriorated significantly. Specifically, the superconducting transition temperatures of the samples of Comparative Example 1 and Comparative Example 2 were respectively 73.0 K and 40.0 K after irradiation with high-energy He ions, exhibiting values lower than the temperature indicated by liquid nitrogen (77.0 K). Therefore, the composites of Comparative Example 1 and Comparative Example 2 could not be utilized as superconductors at the liquid nitrogen temperature before and after irradiation with high-energy particles.

### Evaluation of Irradiation Resistance Relevant to Critical Current Density

With respect to the superconductors of Examples 1 to 3 and Comparative Example 1 to the following Comparative Example 3, the critical current density Je was measured by measuring the magnetic field dependency of magnetization. The measured critical current density J_{c} was evaluated for each sample at each of the temperatures of 2 K, 4.2 K, 10 K, 20 K, 50 K, and 77.3 K under a magnetic field environment of 0 to 7 T.

### Comparative Example 3

Except that the target was changed, a superconducting laminate in which a superconducting layer constituted of a superconductor represented by the composition formula Y_{0.2}Sm_{0.2}Eu_{0.2}Dy_{0.2}Ho_{0.2}Ba₂Cu₃O_{7-δ} was formed on the base layer was produced by a method similar to that of Example 1.

In Comparative Example 3, the target was prepared in the following procedure. In preparing the target, first, regarding the material of the target, Y₂O₃ (purity 99.9%), Sm₂O₃ (purity 99.9%), Eu₂O₃ (purity 99.9%), Dy₂O₃ (purity 99.9%), Ho₂O₃ (purity 99.9%), BaCO₃ (purity 98%), and CuO (purity 99.9%) were weighed in a mass ratio of 1/5:1/5:1/5:1/5:1/5:2:3 (mol) and mixed in a mortar, and a mixed powder was prepared. The firing conditions for producing the target using the mixed powder were similar to those in Example 1.

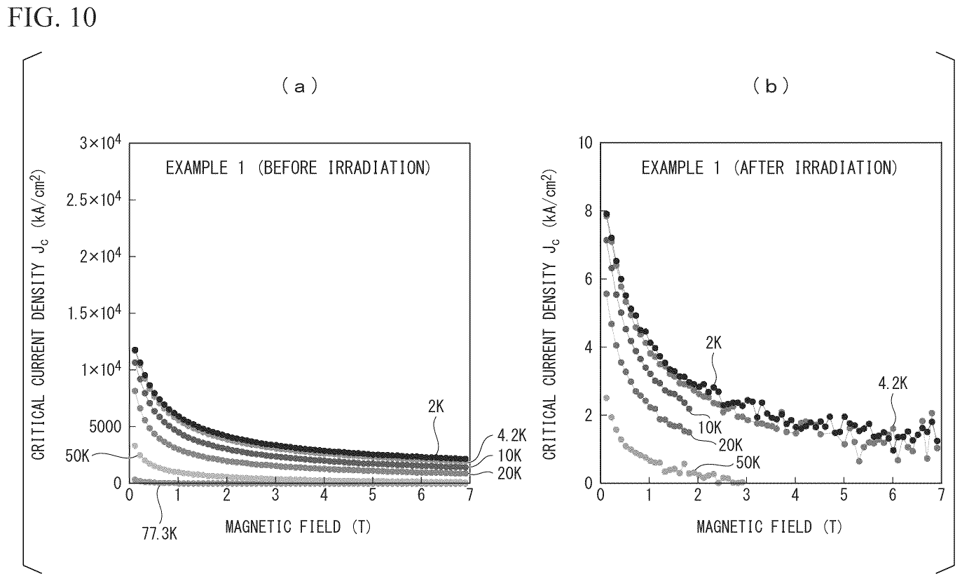

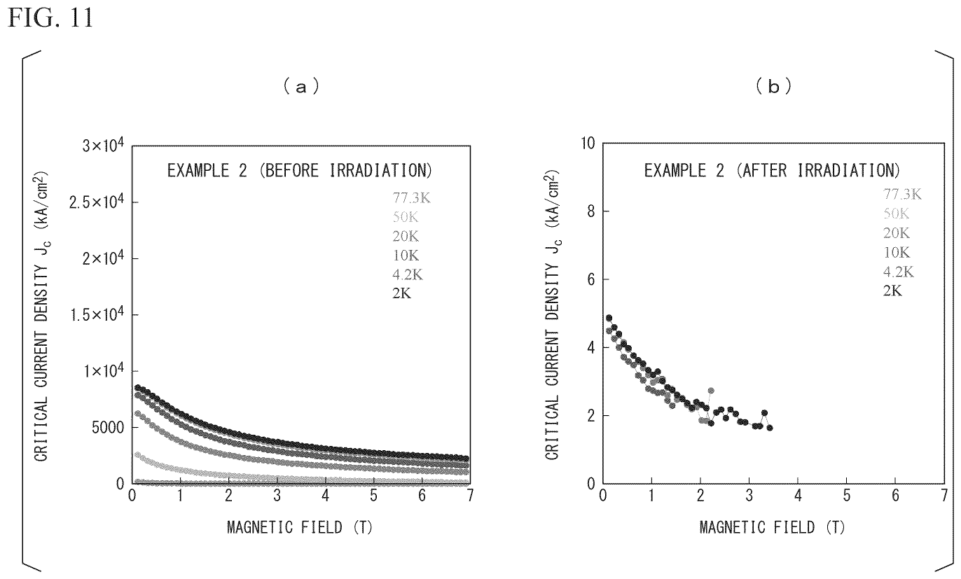

FIG. 10(a) is a graph showing critical current densities before the sample of Example 1 is irradiated with He ions, and FIG. 10(b) is a graph showing critical current densities after the sample of Example 1 is irradiated with He ions.

FIG. 11(a) is a graph showing critical current densities before the sample of Example 2 is irradiated with He ions, and FIG. 11(b) is a graph showing critical current densities after the sample of Example 2 is irradiated with He ions.

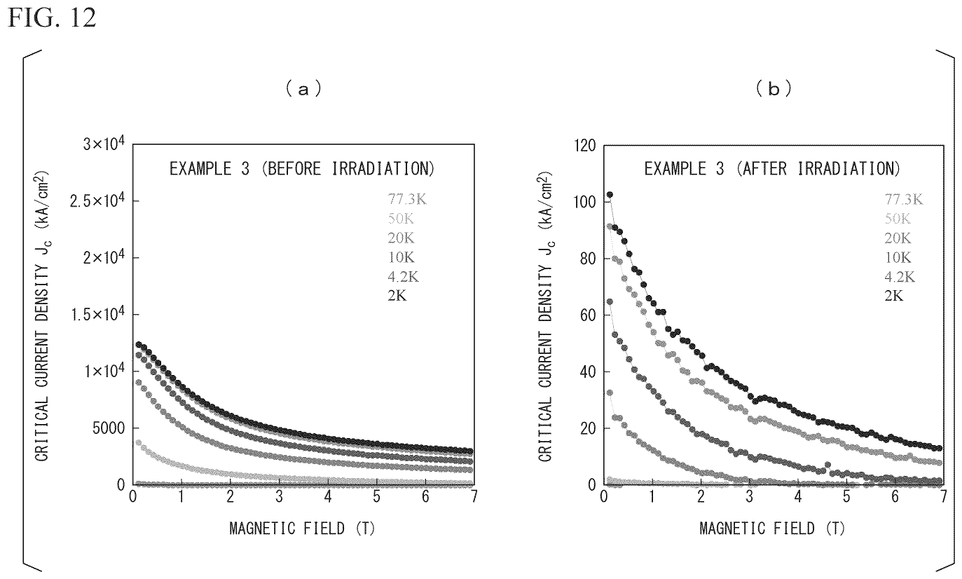

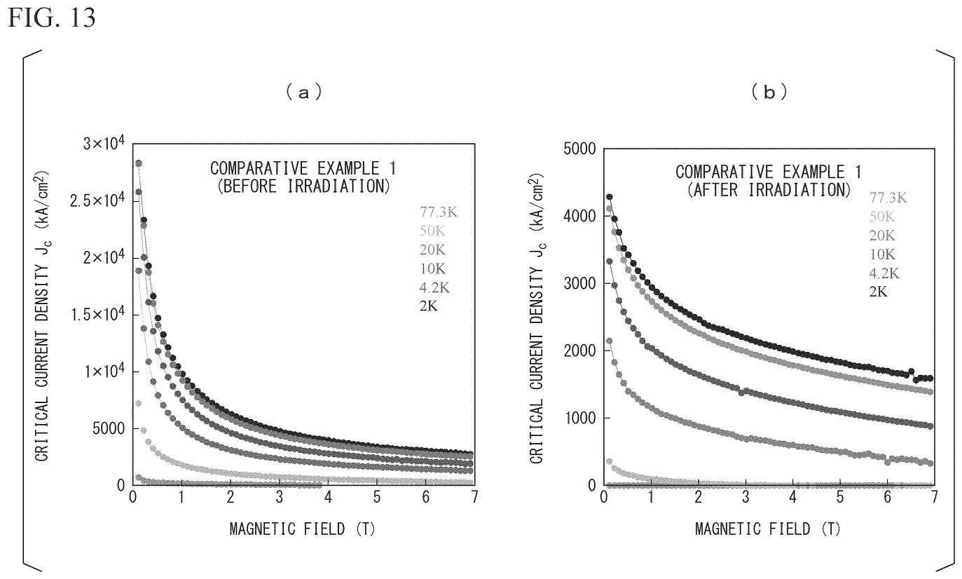

FIG. 12(a) is a graph showing critical current densities before the sample of Example 3 is irradiated with He ions, and FIG. 12(b) is a graph showing critical current densities after the sample of Example 3 is irradiated with He ions.

FIG. 13(a) is a graph showing critical current densities before the sample of Comparative Example 1 is irradiated with He ions, and FIG. 13(b) is a graph showing critical current densities after the sample of Comparative Example 1 is irradiated with He ions.

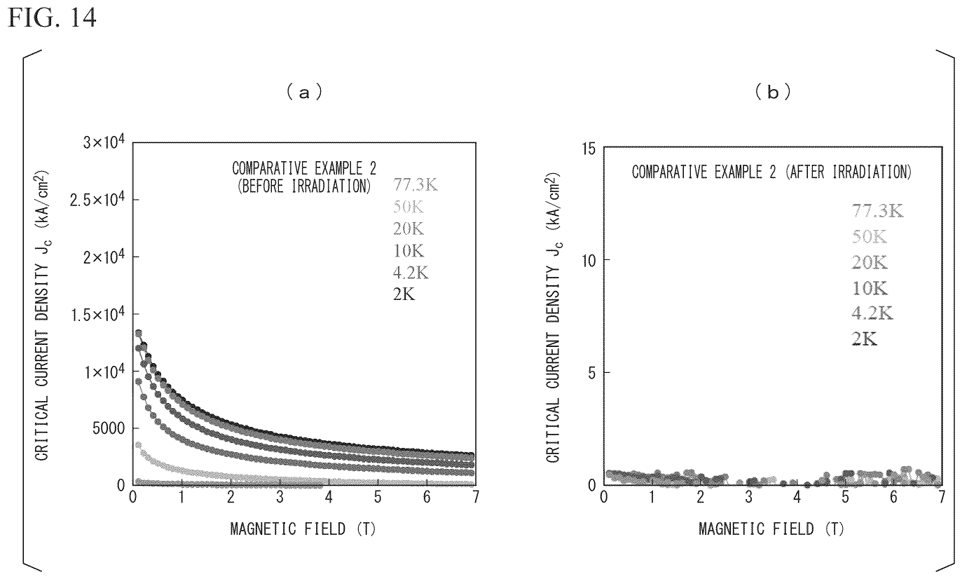

FIG. 14(a) is a graph showing critical current densities before the sample of Comparative Example 2 is irradiated with He ions, and FIG. 14(b) is a graph showing critical current densities after the sample of Comparative Example 2 is irradiated with He ions.

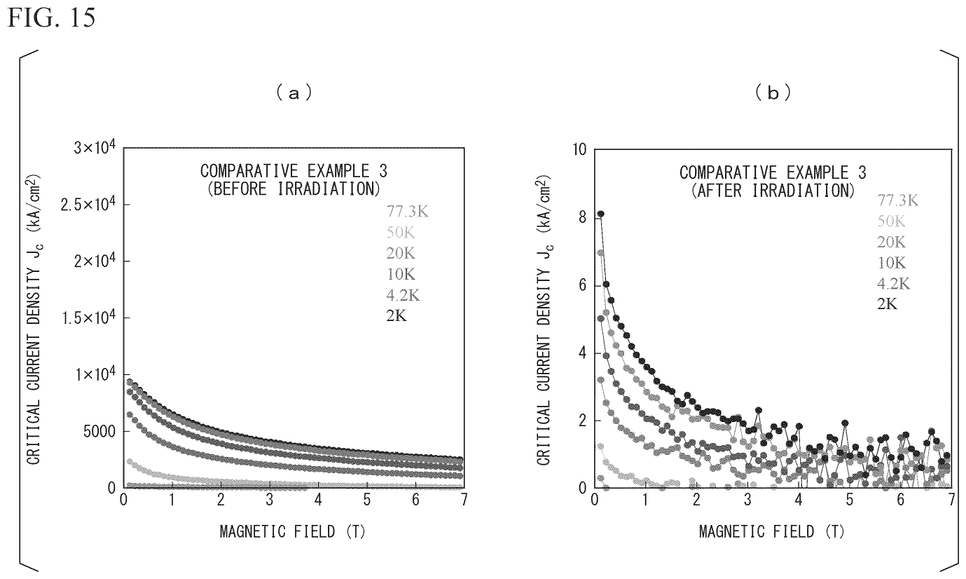

FIG. 15(a) is a graph showing critical current densities before the sample of Comparative Example 3 is irradiated with He ions, and FIG. 15(b) is a graph showing critical current densities after the sample of Comparative Example 3 is irradiated with He ions.

In all of the foregoing graphs, a correlation in which the critical current density was lower at lower temperatures and was higher at higher temperatures, and it was lower under a higher magnetic field environment and was higher under a lower magnetic field environment was confirmed.

It was confirmed that a superconductor having five species of rare earth elements including Y and Gd as the rare earth elements RE as in Example 3 exhibited a higher critical current density than other superconductors containing a plurality of rare earth elements. Therefore, it can be said that the superconductor of Example 3 exhibits a high superconducting transition temperature and a high critical current density even after irradiation with high-energy particles.

In contrast, the superconducting transition temperature is low in the superconductor containing only Y as the rare earth element as in Comparative Example 1 or the superconductor as in Comparative Example 2. In addition, in the superconductor having five species of rare earth elements but not containing Gd as in Comparative Example 3, the critical current density was significantly lower than that of the superconductor of Example 3.

### REFERENCE SIGNS LIST

1 Substrate
2 Intermediate layer
3 Superconducting layer
5 Superconducting laminate
6 Stabilization layer
10 Superconducting wire
12 Base layer
T Target
L Laser light
P Plume
RE Rare earth element

What is claimed is:

1. A superconductor represented by General Formula (1),
REBa₂Cu₃O_{7-δ} (1)
(in Formula (1), RE is composed of Y, Gd, and X, X is composed of one or multiple species of elements selected from the group consisting of La, Ce, Pr, Nd, Sm, Eu, Tb, Dy, Ho, Er, Tm, Yb, and Lu, and 0≤δ≤1).

2. The superconductor according to claim 1,
wherein in the foregoing Formula (1), X is composed of Dy and one or multiple species of elements selected from the group consisting of La, Ce, Pr, Nd, Sm, Eu, Tb, Ho, Er, Tm, Yb, and Lu.

3. The superconductor according to claim 1,
wherein five or more species of rare earth elements are contained therein, and
a mixing entropy ΔSₘᵢₓ of an RE site is 1.5R or greater.

4. The superconductor according to claim 1,
wherein in the foregoing Formula (1), RE is represented by General Formula (2).
YₐGd_{b}X_{c} (2)
(0.05≤a≤0.9, 0.05≤b≤0.9, and 0.05≤c≤0.9)

5. A method for manufacturing a superconductor comprising:
a preparation step of preparing a base layer having a surface constituted of single crystal; and
a vapor deposition step of vapor-depositing a superconductor on the base layer,
wherein in the vapor deposition step, a target represented by General Formula (1) is used.
REBa₂Cu₃O_{7-δ} (1)
(in Formula (1), RE is composed of Y, Gd, and X, X is composed of one or multiple species of elements selected from the group consisting of La, Ce, Pr, Nd, Sm, Eu, Tb, Dy, Ho, Er, Tm, Yb, and Lu, and 0≤δ≤1)

6. The method for manufacturing a superconductor according to claim 5,
wherein in the vapor deposition step, the target is disposed at a position facing the base layer, and the target is irradiated with a pulsed laser.
